(19) United States
(12) Patent Application Publication
(10) Pub. No.: US 2026/0040657 A1
(43) Pub. Date: Feb. 5, 2026

(54) METHOD OF MANUFACTURING INTEGRATED CIRCUIT DEVICE

(71) Applicant: Samsung Electronics Co., Ltd., Suwon-si (KR)

(72) Inventors: Sangcheol Na, Suwon-si (KR); Minchan Gwak, Suwon-si (KR); Kyoungwoo Lee, Suwon-si (KR); Seungseok Ha, Suwon-si (KR)

(21) Appl. No.: 19/014,915

(22) Filed: Jan. 9, 2025

(30) Foreign Application Priority Data
Aug. 1, 2024 (KR) 10-2024-0102704

(51) Int. Cl. H10D 84/01; H10D 30/01; H10D 84/83

(52) U.S. Cl. CPC H10D 84/0149; H10D 30/014; H10D 30/0191; H10D 84/0128; H10D 84/013; H10D 84/832

(57) ABSTRACT

A method includes alternately stacking a plurality of sacrificial layers and a plurality of channel layers on a first surface of a substrate; dividing the plurality of channel layers into a plurality of nanosheet stacks; forming a placeholder and a source/drain region on the placeholder between the plurality of nanosheet stacks; forming a first gate structure in an area from which the plurality of sacrificial layers have been removed; etching a portion of a second surface of the substrate to form an opening in the substrate and forming a backside insulating structure in the opening; etching the substrate so that at least a portion of the placeholder is exposed; removing the placeholder; and forming a liner on at least a portion of a side surface of the substrate from which the placeholder has been removed and forming a backside contact on the liner.

### CROSS-REFERENCE TO RELATED APPLICATION

This application is based on and claims priority under 35 U.S.C. § 119 to Korean Patent Application No. 10-2024-0102704, filed on Aug. 1, 2024, in the Korean Intellectual Property Office, the disclosure of which is incorporated by reference herein in its entirety.

### BACKGROUND

The inventive concept relates to a method of manufacturing an integrated circuit device. More particularly, the inventive concept relates to a method of manufacturing an integrated circuit device with a power delivery network (PDN) formed on the backside thereof.

With the development of electronics technology, downscaling of integrated circuit devices has rapidly progressed. To efficiently transmit power to a highly-integrated integrated circuit device, an integrated circuit device with a PDN on the backside thereof has been introduced. Because the integrated circuit device has a complex structure and is also highly densified, the operational reliability thereof may be degraded due to a leakage current and thus an integrated circuit device with improved operational reliability may be desired.

### SUMMARY

Embodiments of the inventive concept provide an integrated circuit device with improved operational characteristics and improved reliability.

Also, the problems to be solved by the inventive concept are not limited to the above problems, and other problems may be clearly understood by those of ordinary skill in the art from the following description.

To achieve the technical objects, the inventive concept provides the following methods of manufacturing an integrated circuit device.

According to an aspect of the inventive concept, there is provided a method of manufacturing an integrated circuit device, the method including alternately stacking a plurality of sacrificial layers and a plurality of channel layers on a first surface of a substrate including the first surface and a second surface opposite to the first surface, etching a portion of each of the plurality of sacrificial layers and the plurality of channel layers to divide the plurality of channel layers into a plurality of nanosheet stacks, forming a placeholder and a source/drain region on the placeholder between the plurality of nanosheet stacks, removing the plurality of sacrificial layers and forming a first gate structure including a gate dielectric layer and a gate line in an area from which the plurality of sacrificial layers have been removed, etching a portion of the second surface of the substrate in an area where the first gate structure is arranged in a plan view to form an opening in the substrate and forming a backside insulating structure in the opening including a lower surface facing the first surface of the substrate and an upper surface facing the second surface of the substrate, etching the substrate so that at least a portion of the placeholder is exposed, removing the placeholder, and forming a liner on at least a portion of a side surface of the substrate from which the placeholder has been removed and forming a backside contact on the liner.

According to another aspect of the inventive concept, there is provided a method of manufacturing an integrated circuit device, the method including alternately stacking a plurality of sacrificial layers and a plurality of channel layers layer by layer on a first surface of a substrate including the first surface and a second surface opposite to the first surface, etching a portion of each of the plurality of sacrificial layers and the plurality of channel layers to divide the plurality of channel layers into a plurality of nanosheet stacks, forming a source/drain region between the plurality of nanosheet stacks, removing the plurality of sacrificial layers and forming a first gate structure including a gate dielectric layer and a gate line in an area from which the plurality of sacrificial layers have been removed, etching a portion of the second surface of the substrate in an area where the first gate structure is arranged in a plan view to form an opening in the substrate and forming a backside insulating structure in the opening including a lower surface facing the first surface of the substrate and an upper surface facing the second surface of the substrate, etching the substrate so that at least a portion of the source/drain region is exposed, and forming a liner on an exposed surface of the source/drain region and on at least a portion of a side surface of the substrate and forming a backside contact on the liner.

According to another aspect of the inventive concept, there is provided a method of manufacturing an integrated circuit device, the method including forming a placeholder, a source/drain region, and a first gate structure including a gate dielectric layer and a gate line on a first surface of a substrate including the first surface and a second surface opposite to the first surface, etching a portion of the second surface of the substrate in an area where the first gate structure is arranged in a plan view to form an opening in the substrate and forming a backside insulating structure in the opening, forming a backside insulating layer on an upper surface of the backside insulating structure and the second surface of the substrate, and an interlayer insulating layer on the backside insulating layer, removing a portion of the interlayer insulating layer and the backside insulating layer to expose a portion of the substrate and forming a hole in the substrate so that at least a portion of the placeholder is exposed, removing the placeholder and forming a silicide liner on a side surface and a lower surface of the hole, to a vertical level lower than the backside insulating layer where the first surface of the substrate provides a base reference plane and the second surface of the substrate is above the first surface of the substrate, in a space from which the placeholder has been removed, and forming a backside contact in a space bordered by the liner and an empty space in the interlayer insulating layer.

### BRIEF DESCRIPTION OF DRAWINGS

Embodiments will be more clearly understood from the following detailed description taken in conjunction with the accompanying drawings in which:

FIGS. 1-14, 15A, 15B, 16A, 16B, 17A, 17B, 18A, 18B, 19A, 19B, 20A, 20B, 21A, and 21B are cross-sectional views sequentially illustrating operations of manufacturing an integrated circuit device according to some embodiments; and

FIGS. 22A, 22B, 23A, and 23B are cross-sectional views sequentially illustrating operations of manufacturing an integrated circuit device according to further embodiments.

### DETAILED DESCRIPTION OF THE EMBODIMENTS

Hereinafter, embodiments will be described in detail with reference to the accompanying drawings. Herein, like reference numerals will denote like elements, and redundant descriptions thereof will be omitted for conciseness. As used herein, the term “and/or” includes any and all combinations of one or more of the associated listed items. It will be understood that when an element is referred to as being “on,” “attached” to, “connected” to, “coupled” with, “contacting,” etc., another element, it can be directly on, attached to, connected to, coupled with or contacting the other element or intervening elements may also be present. In contrast, when an element is referred to as being, for example, “directly on,” “directly attached” to, “directly connected” to, “directly coupled” with or “directly contacting” another element, there are no intervening elements present. It will be understood that, although the terms “first,” “second,” etc. may be used herein to describe various elements or components, these elements or components should not be limited by these terms. These terms are only used to distinguish one element or component from another element or component. Therefore, a first element or component discussed below could be termed a second element or component without departing from the technical spirits of the present disclosure. It is noted that aspects described with respect to one embodiment may be incorporated in different embodiments although not specifically described relative thereto. That is, all embodiments and/or features of any embodiments can be combined in any way and/or combination.

The inventive concept may include various embodiments and modifications, and certain embodiments are illustrated in the drawings and will be described below in detail. However, this is not intended to limit the inventive concept to particular embodiments, and it should be understood as including all modifications, equivalents, and substitutes included in the spirit and scope of the inventive concept. In the following description of the embodiments, certain detailed descriptions of the related art will be omitted when it is deemed that they may unnecessarily obscure the subject matters of the embodiments.

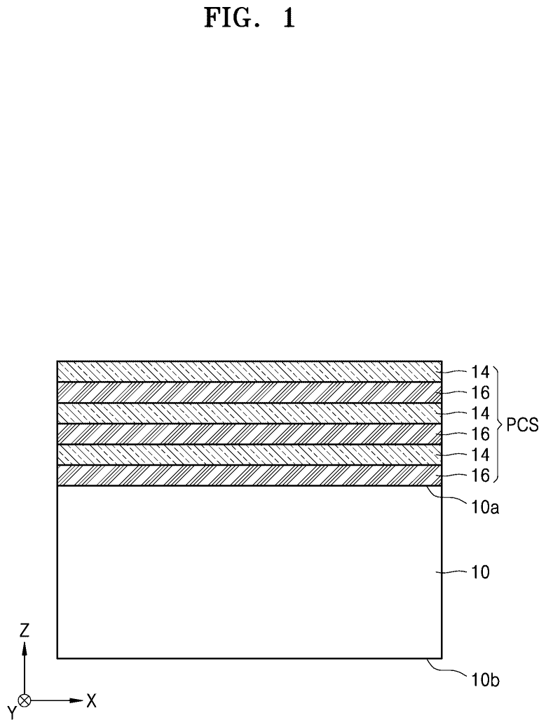

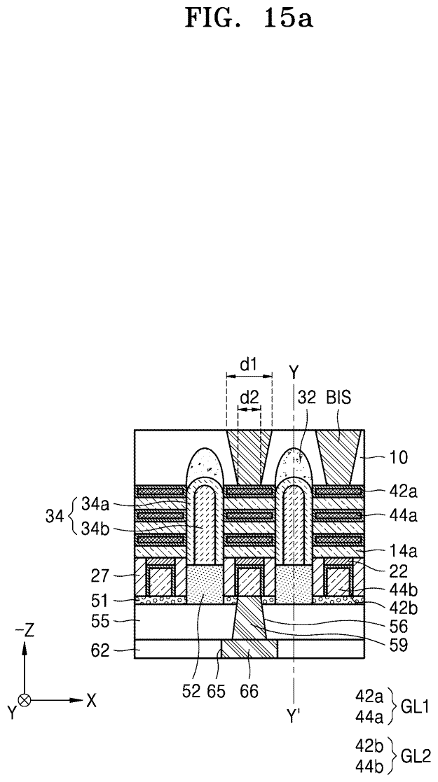

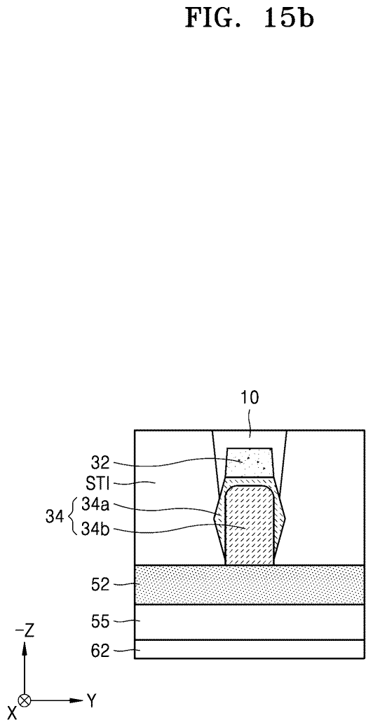

FIGS. 1-14, 15A, 15B, 16A, 16B, 17A, 17B, 18A, 18B, 19A, 19B, 20A, 20B, 21A, and 21B are cross-sectional views sequentially illustrating operations of manufacturing an integrated circuit device according to embodiments. Particularly, FIGS. 1, 2, 3, 4, 5, 6, 7, 8, 9, 10, 11, 12, 13, 14, 15A, 16A, 17A, 18A, 19A, 20A, and 21A are cross-sectional views illustrating a process of manufacturing an integrated circuit device in an X direction, and FIGS. 15B, 16B, 17B, 18B, 19B, 20B, and 21B are cross-sectional views illustrating cross-sections taken along lines Y-Y of FIGS. 15A, 16A, 17A, 18A, 19A, 20A, and 21A respectively.

Referring to FIGS. 1-14, 15A, 15B, 16A, 16B, 17A, 17B, 18A, 18B, 19A, 19B, 20A, 20B, 21A, and 21B, the X direction may be a first horizontal direction, and a Y direction may be a second horizontal direction perpendicular to the first horizontal direction. A Z direction may be a vertical direction perpendicular to a plane formed by the X direction and the Y direction.

The integrated circuit device according to embodiments may constitute a logic cell including a multi-bridge channel FET (MBCFET) device. However, embodiments of the inventive concept are not limited thereto, and the integrated circuit device may include a planar FET device, a gate-all-around type FET device, and a FinFET device, a FET device based on a two-dimensional material, such as a MoS2 semiconductor gate electrode, or the like.

Referring to FIG. 1, a preliminary channel stack PCS may be formed on a substrate 10. The preliminary channel stack PCS may include a plurality of first channel layers 14 and a plurality of sacrificial layers 16. In the present embodiment, each of the sacrificial layers 16 and the first channel layers 14 is illustrated as being formed to be stacked three times on the substrate 10; however, the inventive concept is not limited thereto.

The substrate 10 may include a first surface 10a on a frontside in the vertical direction (Z direction) and a second surface 10b on a backside corresponding to the first surface 10a. In some embodiments, the substrate 10 may include a group IV semiconductor, such as Si or Ge, a group IV-IV compound semiconductor such as SiGe or SiC, or a group III-V compound semiconductor, such as GaAs, InAs, or InP. In some embodiments, the substrate 10 may include a bulk silicon substrate; however, embodiments of the inventive concept are not limited thereto. As described below, the substrate 10 may not be completely removed in a subsequent process.

Moreover, the plurality of sacrificial layers 16 and the plurality of first channel layers 14 constituting the preliminary channel stack PCS may be formed by epitaxial growth. The plurality of sacrificial layers 16 and the plurality of first channel layers 14 may include different semiconductor materials.

In some embodiments, the sacrificial layers 16 may include SiGe, and the first channel layers 14 may include Si; however, embodiments of the inventive concept are not limited thereto. All of the plurality of sacrificial layers 16 and the plurality of first channel layers 14 may be formed to the same thickness; however, embodiments of the inventive concept are not limited thereto.

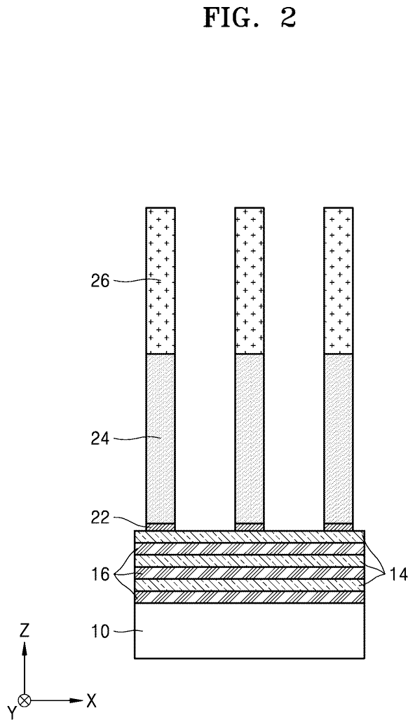

Referring to FIG. 2, a preliminary mask pattern may be formed on the preliminary channel stack PCS. As for the preliminary mask pattern, an insulating layer 22, a dummy polysilicon layer 24, and a capping insulating layer 26 may be sequentially formed on the first channel layer 14 formed on the uppermost portion of the preliminary channel stack PCS and then a plurality of preliminary mask patterns may be formed at certain intervals in the first horizontal direction (X direction) by using an etch mask (not illustrated). The dummy polysilicon layer 24 may include a doped layer. The capping insulating layer 26 may be formed as a silicon nitride layer.

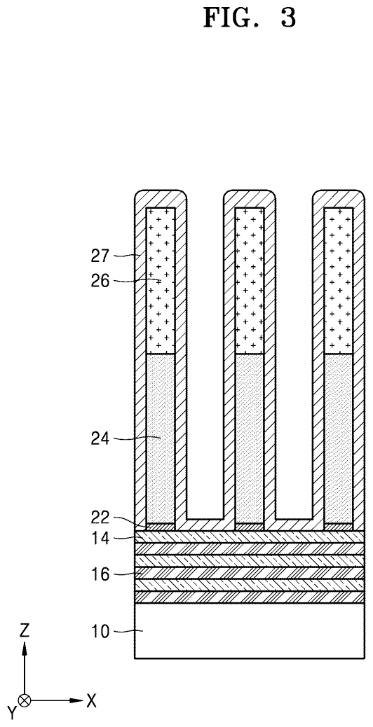

Referring to FIG. 3, a spacer insulating layer 27 may be formed over the front surface of the substrate 10. The spacer insulating layer 27 may be formed to a substantially uniform thickness on the exposed surfaces of the insulating layer 22, the dummy polysilicon layer 24, the capping insulating layer 26, and the first channel layer 14. The spacer insulating layer 27 may be formed as a silicon oxide layer.

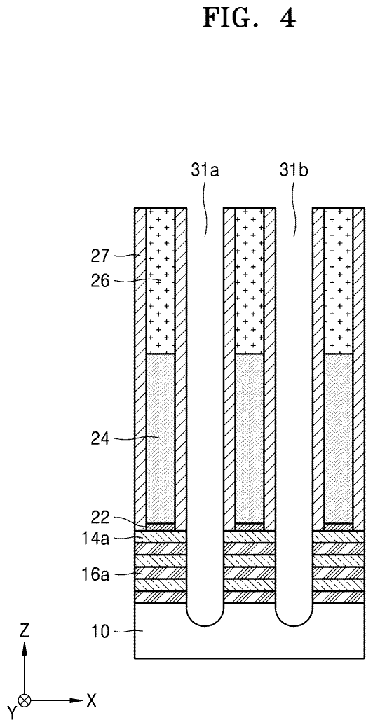

Referring to FIG. 4, a blanket etching process may be performed on the spacer insulating layer 27 to form the spacer insulating layer 27 on the sidewall of the preliminary mask pattern to form a mask pattern. The mask pattern may include the insulating layer 22, the dummy polysilicon layer 24, the capping insulating layer 26, and the spacer insulating layer 27. A first opening portion 31a and a second opening portion 31b are formed between the mask patterns. By performing an etching process by using the mask pattern with the first opening portion 31a and the second opening portion 31b formed therein as an etch mask, a first preliminary source/drain region may be formed in the first opening portion 31a and a second preliminary source/drain region may be formed in the second opening portion 31b. The etching process using the mask pattern with the first opening portion 31a and the second opening portion 31b formed therein as an etch mask may be performed until the opening portions extend to a certain depth below the first surface 10a of the substrate 10 while passing through the preliminary channel stack PCS.

By the etching process, a portion of the preliminary channel stack PCS may be removed and thus the preliminary channel stack PCS may be separated in the first horizontal direction (X direction). This results in the plurality of channel layers 14 being divided into a plurality of nanosheet stacks.

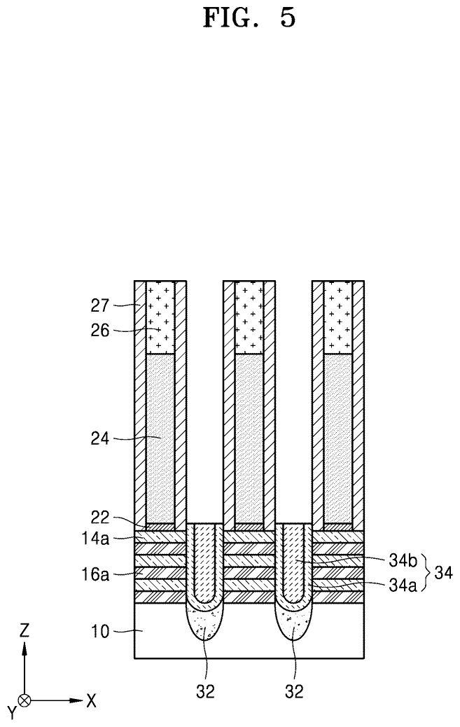

Referring to FIG. 5, a first placeholder 32 (a placeholder illustrated on the left side of FIG. 5) and a second placeholder 32 (a placeholder illustrated on the right side of FIG. 5) may be formed on the exposed substrate 10 of the first preliminary source/drain region and the second preliminary source/drain region, i.e., the first and second opening portions 31a and 31b, respectively. The placeholder 32 may include an epitaxial layer formed by selectively epitaxially growing a semiconductor material on an exposed portion of the substrate 10. In some embodiments, the placeholder 32 may include an epitaxially grown Si layer, an epitaxially grown SiC layer, or an epitaxially grown SiGe layer. In the present embodiment, the placeholder may include an epitaxially grown SiGe layer.

Subsequently, a doped semiconductor material may be selectively epitaxially grown on the epitaxially grown placeholder 32 to form a source/drain region 34. The source/drain region 34 may include a single source/drain region 34 having a uniform dopant concentration. In some embodiments, the source/drain region 34 may include, for example, an inner source/drain region 34b located on the inner side thereof and an outer source/drain region 34a at least partially surrounding the inner source/drain region 34b. The inner source/drain region 34b and the outer source/drain region 34a may be distinguished by a difference in dopant concentration. In some embodiments, the dopant concentration of the inner source/drain region 34b may be greater than the dopant concentration of the outer source/drain region 34a; however, embodiments of the inventive concept are not limited thereto.

In some embodiments, the dopant may include boron (B), arsenic (As), and/or phosphorus (P). The source/drain region 34 may include a doped SiGe layer, a doped Ge layer, a doped SiC layer, or a doped InGaAs layer; however, embodiments of the inventive concept are not limited thereto.

Moreover, in the embodiment of a PMOS transistor and an NMOS transistor, the placeholder 32 may be different from the source/drain region 34 due to their operational characteristics. A process of forming a placeholder and a source/drain region in an area where a PMOS transistor is formed and a process of forming a placeholder and a source/drain region in an area where an NMOS transistor is formed may be performed in different operations.

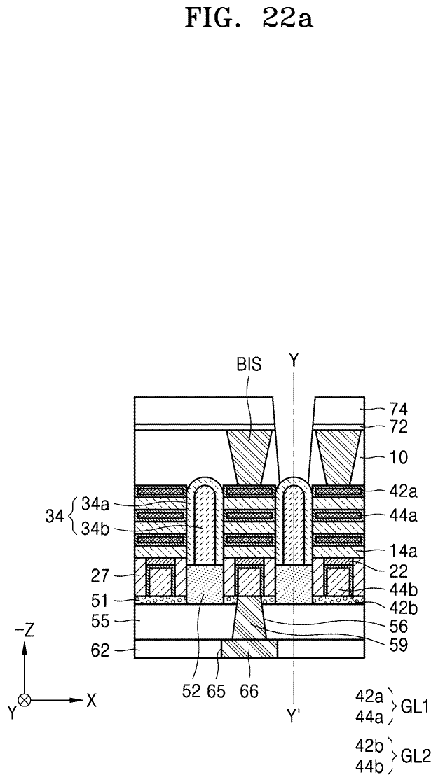

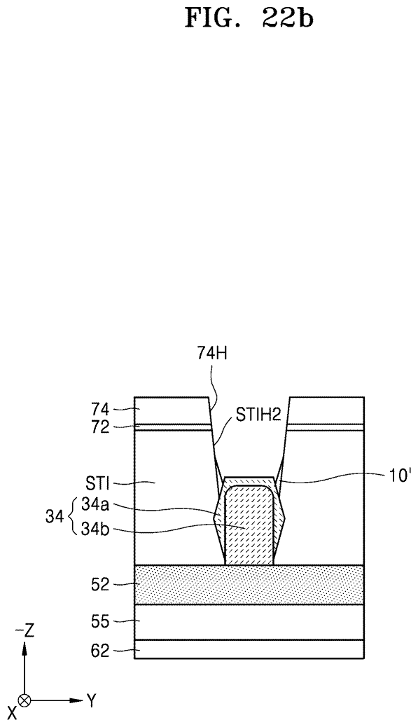

Moreover, the placeholder may not be formed under the source/drain region 34. In some embodiments, instead of the placeholder being formed, the lower portion of the source/drain region 34 may protrude downward from the first surface 10a that is the upper surface of the substrate 10. The embodiment where the placeholder is not formed will be described below with reference to FIGS. 22A and 22B.

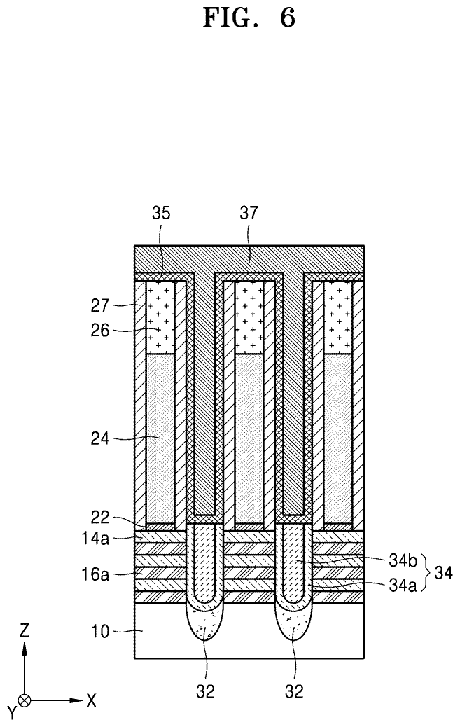

Referring still to FIG. 6, an insulating layer may be formed on the front surface of the substrate 10 where the source/drain region 34 has been formed, to at least partially fill the first opening portion 31a and the second opening portion 31b (see FIG. 4). The insulating layer may include a liner insulating layer 35 and a filling insulating layer 37. In some embodiments, the liner insulating layer 35 may include a silicon nitride layer, and the filling insulating layer 37 may include a silicon oxide layer. In some embodiments, the filling insulating layer 37 may include a polysilazane layer referred to as tonene silazene (TOSZ); however, embodiments of the inventive concept are not limited thereto.

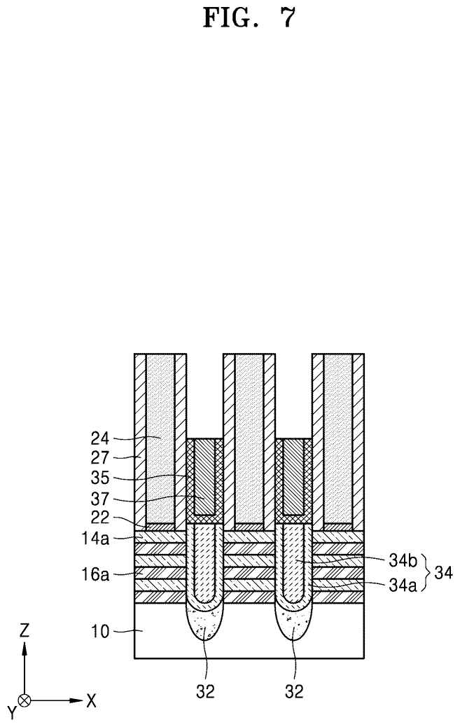

Referring to FIG. 7, an etching process may be performed on the resulting structure of FIG. 6, such that a portion of the liner insulating layer 35 and the filling insulating layer 37 remains on the source/drain region 34. In this embodiment, the capping insulating layer 26 may be removed from the mask pattern for defining the first preliminary source/drain region and the second preliminary source/drain region, to at least partially expose the dummy polysilicon layer 24.

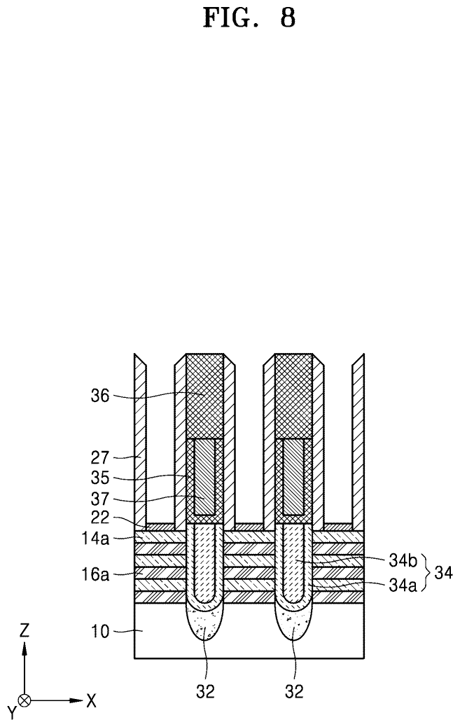

Referring to FIG. 8, a mask insulating layer 36 for removing the dummy polysilicon layer 24 may be formed on a portion where a portion of the liner insulating layer 35 and the filling insulating layer 37 remains on the first source/drain region 34 and the second source/drain region 34. In some embodiments, the mask insulating layer 36 may include a silicon nitride layer. The mask insulating layer 36 may be obtained by forming a mask insulating layer material on the front surface of the resulting structure of FIG. 7, at least partially filling a space on the liner insulating layer 35 and the filling insulating layer 37 partially remaining on the first source/drain region 34 and the second source/drain region 34, and then performing an etching process so that the dummy polysilicon layer 24 is exposed.

Referring still to FIG. 8, only the exposed dummy polysilicon layer 24 may be selectively removed. In this case, the insulating layer 22 under the dummy polysilicon layer 24 may remain or may be removed.

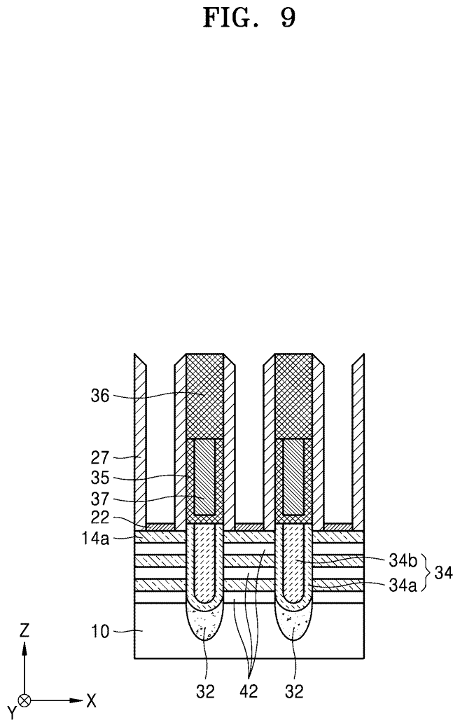

Referring to FIG. 9, the plurality of sacrificial layers (16, 16a) may be selectively removed from the preliminary channel stack PCS (see FIG. 1). A process of removing the plurality of sacrificial layers (16, 16a) may be performed through a radical-assisted SiGe etch (RASE) process. Portions from which the plurality of sacrificial layers (16, 16a) have been removed in the spare channel stack PCS may generate a plurality of first spaces 42. The surfaces of the first channel layers (14, 14a) may be exposed through the first spaces 42.

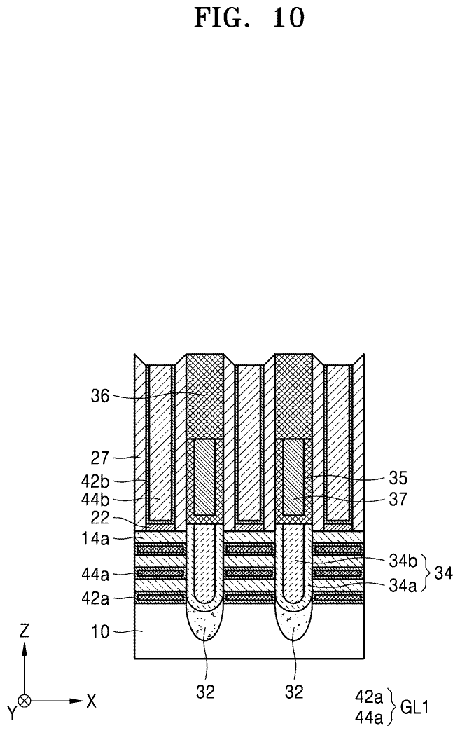

Referring to FIG. 10, a first gate insulating layer 42a may be thinly formed on the surfaces of the first channel layers (14, 14a) exposed through the first spaces 42. The first gate insulating layers 42a may not completely fill the first spaces 42, and a second space smaller than the first space 42 may remain.

The first gate insulating layer 42a may include a high-dielectric layer. The high-dielectric layer may include a material having a higher dielectric constant than a silicon oxide layer. For example, the high-dielectric layer may have a dielectric constant of about 10 to about 25. The high-dielectric layer may include a material selected from among hafnium oxide, hafnium oxynitride, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and any combination thereof; however, the material constituting the high-dielectric layer is not limited thereto.

The high-dielectric layer may be formed by an atomic layer deposition (ALD), chemical vapor deposition (CVD), or physical vapor deposition (PVD) process. The high-dielectric layer may have a thickness of about 10 Å to about 40 Å; however, embodiments of the inventive concept are not limited thereto.

Moreover, a second gate insulating layer 42b may also be formed on the exposed surfaces of the spacer insulating layer 27 and the insulating layer 22 simultaneously or in concert with the formation of the first gate insulating layer 42a. The first gate insulating layer 42a and the second gate insulating layer 42b may be formed through the same deposition process and may be formed of the same material.

Referring still to FIG. 10, a replacement metal gate (RMG) may be formed on the first gate insulating layer 42a to form a first gate electrode layer 44a in the remaining second space. In this embodiment, a second gate electrode layer 44b may be simultaneously formed on the second gate insulating layer 42b.

The first gate electrode layer 44a and the second gate electrode layer 44b may include a metal layer or a metal nitride layer. In some embodiments, the first gate electrode layer 44a and the second gate electrode layer 44b may include at least one material selected from among Ti, W, Al, Ru, Nb, Mo, Hf, Ni, Co, Pt, Yb, Tb, Dy, Er, Pd, TiN, and/or TaN.

Referring to FIG. 10, a first gate structure GL1 may include a plurality of first gate electrode layers 44a and a plurality of first gate insulating layers 42a. Each of the first gate electrode layers 44a, the first gate insulating layer 42a in contact therewith, and the first channel layer 14a corresponding to the first gate electrode layer 44a with the first gate insulating layer 42a therebetween may form a transistor together with the source/drain regions arranged on the left and right sides thereof. In FIG. 10, the first gate structure GL1 is illustrated as including three first gate electrode layers 44a formed in the vertical direction; however, embodiments of the inventive concept are not limited thereto. For example, at least one first gate electrode layer 44a may be formed.

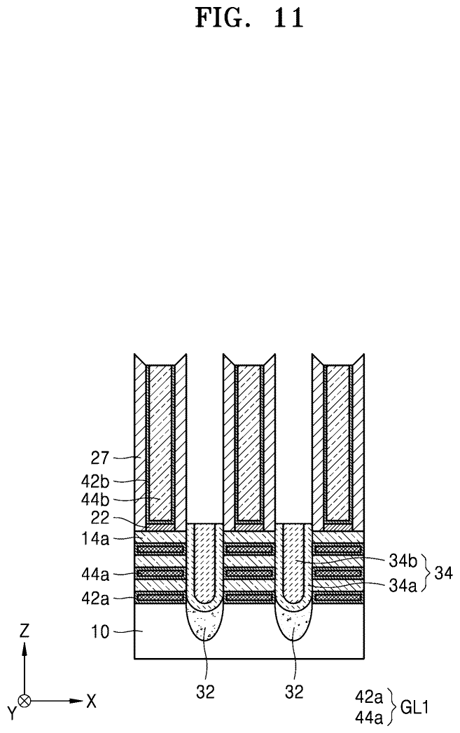

Referring to FIG. 11, the liner insulating layer 35, the filling insulating layer 37, and the mask insulating layer 36 may be removed, such that the first and second source/drain regions 34 are at least partially exposed.

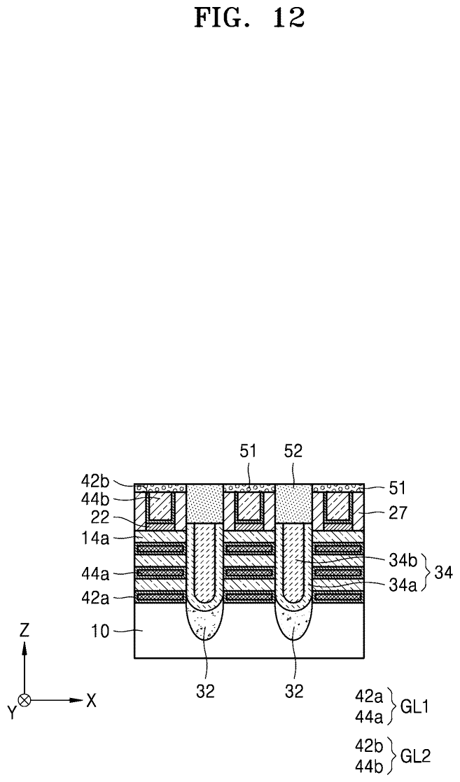

Referring to FIG. 12, after forming a second gate structure GL2, a first interlayer insulating layer 52 may be formed on the first and second source/drain regions 34, a gate capping layer 51 may be formed on the second gate structure GL2, and then surface planarization may be performed thereon.

The second gate structure GL2 may include a second gate insulating layer 42b and a second gate electrode layer 44b. The first channel layer 14a, the second gate insulating layer 42b, and the second gate electrode layer 44b in the form of a nanosheet located over the frontside may form a transistor together with the source/drain regions arranged on the left and right sides thereof. Thus, the first gate structure GL1 and the second gate structure GL2 and the plurality of first channel layers 14a arranged therebetween in the form of a nanosheet may form a transistor together with the source/drain regions arranged on the left and right sides thereof.

Referring to FIGS. 11 and 12 together, in the resulting structure of FIG. 10, without removing the liner insulating layer 35, the filling insulating layer 37, and the mask insulating layer 36, a chemical mechanical polishing (CMP) process may be performed on the front surface thereof to form a second gate electrode layer 44b with a desired height, and then the liner insulating layer 35, the filling insulating layer 37, and the mask insulating layer 36 may be removed. Subsequently, a first interlayer insulating layer 52 may be formed to at least partially fill a portion where the liner insulating layer 35, the filling insulating layer 37, and the mask insulating layer 36 have been removed (i.e., on the upper side of the first and second source/drain regions 34), a gate capping layer 51 may be formed on the second gate electrode layer 44b, the second gate insulating layer 42b, and the spacer insulating layer 27 forming the second gate structure GL2, and then surface planarization may be performed thereon. In some embodiments, the first interlayer insulating layer 52 may include a silicon oxide layer, and the gate capping layer 51 may be formed of a material having an etch selectivity with respect to the first interlayer insulating layer 52. For example, the gate capping layer 51 may include a silicon nitride layer, a silicon oxynitride layer, a silicon oxycarbide layer, and/or a silicon oxycarbonitride layer.

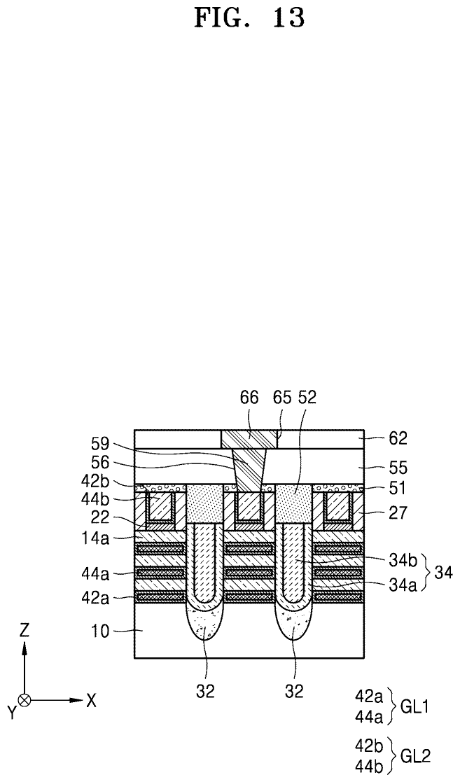

Referring to FIG. 13, a second interlayer insulating layer 55 may be formed on the first interlayer insulating layer 52 and the gate capping layer 51, a portion of the second interlayer insulating layer 55 may be removed to form a second contact hole 56, and then the second contact hole 56 may be at least partially filled to form a second via plug 59.

Subsequently, a third interlayer insulating layer 62 may be formed on the second interlayer insulating layer 55, and then a third contact hole 65 may be formed, and then the third contact hole 65 may be at least partially filled to form a gate connection line layer 66. The second via plug 59 and the gate connection line layer 66 may constitute a second conductive line configured to apply an operation voltage to the gate electrodes (44a, 44b) of the first and second gate structures. The second via plug 59 may be referred to as a frontside gate contact structure.

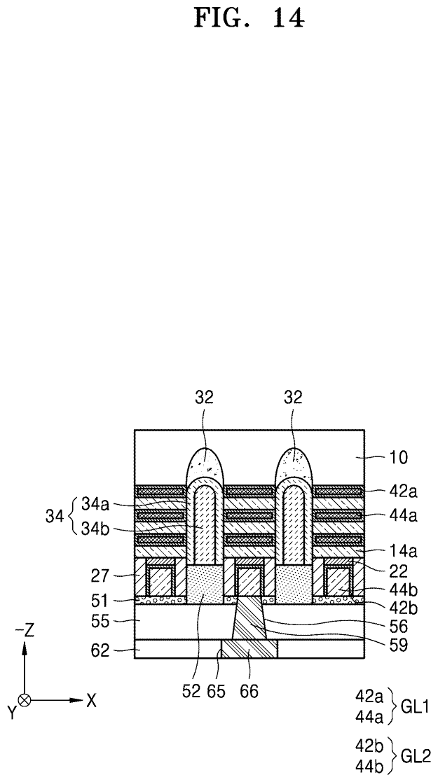

Referring to FIG. 14, the structure of FIG. 13 may be turned over.

Referring to FIGS. 15A and 15B, a portion of the substrate 10 may be etched to form a hole, and a backside insulating structure BIS may be formed in the space thereof. In some embodiments, the backside insulating structure BIS may include silicon nitride. However, embodiments of the inventive concept are not limited thereto, and the backside insulating structure BIS may also include SiOC or other oxides.

Also, in FIGS. 15A and 15B and the following diagrams, the backside insulating structure BIS is illustrated as including a single material; however, this is only for convenience of illustration and the backside insulating structure BIS may include an insulating structure including multiple layers.

At least a portion of the lower surface of the backside insulating structure BIS may contact the first gate insulating layer 42a arranged at a vertical level closest to the back surface of the substrate 10. In another embodiment, the lower surface of the backside insulating structure BIS may entirely contact the first gate insulating layer 42a. However, embodiments of the inventive concept are not limited thereto, and in some other embodiments, even when the backside insulating structure BIS does not directly physically contact the first gate insulating layer 42a, the backside insulating structure BIS may perform a function of preventing or reducing the electrical conduction between adjacent first gate structures GL1.

As illustrated in FIG. 15A, due to a process of forming a hole before at least partially filling the backside insulating structure BIS, the backside insulating structure BIS may have a tapered shape decreasing in width toward the first gate insulating layer 42a. That is, as for the backside insulating structure BIS, a first width d1 in the first horizontal direction (X direction) of one end portion arranged at the same vertical level as the back surface of the substrate 10 may be greater than a second width d2 in the first horizontal direction (X direction) of the other end portion contacting the first gate insulating layer 42a. In some embodiments, the width of the backside insulating structure BIS may monotonically decrease from the second surface of the substrate 10 towards the first surface of the substrate 10.

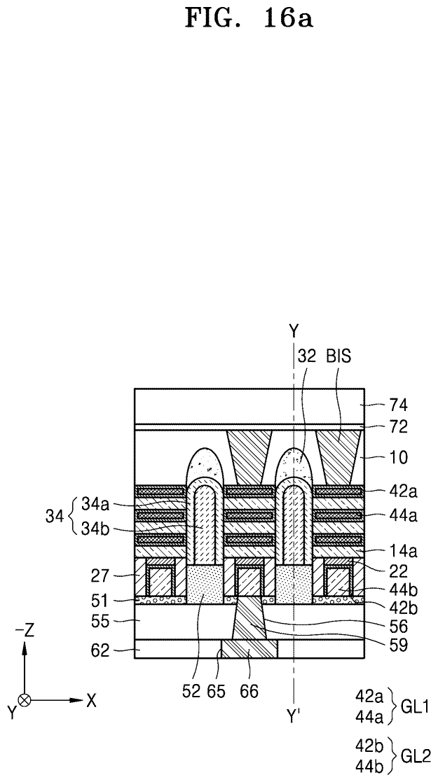

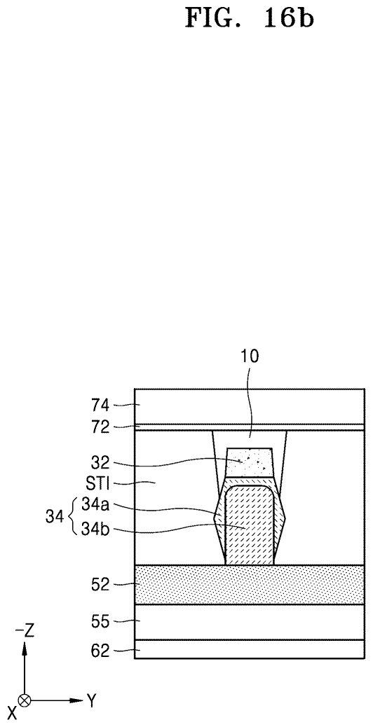

The backside insulating structure BIS may include multiple layers as described above, and in the case of including multiple layers, in some embodiments, the process may be performed in the same manner as in FIGS. 15A and 15B, a multi-layer backside insulating structure BIS may be obtained by at least partially filling the remaining space after primarily applying a material constituting the backside insulating layer 72 (see FIGS. 16A and 16B) before at least partially filling the hole with a single-layer backside insulating structure BIS.

Referring to FIGS. 16A and 16B, a backside insulating layer 72 and a fourth interlayer insulating layer 74 on and at least partially covering the back surface of the substrate 10 and the upper surface of the backside insulating structure BIS may be formed. In some embodiments, the backside insulating layer 72 may include any material selected from among AlO, SiOC, and a combination thereof; however, the inventive concept is not limited thereto. In some embodiments, the fourth interlayer insulating layer 74 may include TEOS; however, embodiments of the inventive concept are not limited thereto.

Although not separately illustrated, instead of separately forming the backside insulating layer 72 and the fourth interlayer insulating layer 74, the material (e.g., SiOC or other oxides) constituting the backside insulating structure BIS in the processes of FIGS. 15A and 15B may be formed in a bulk form so as to entirely cover not only the hole in which the backside insulating structure BIS is to be arranged but also the back surface of the substrate 10. That is, the backside insulating structure BIS and the fourth interlayer insulating layer 74 may be integrally formed, and the fourth interlayer insulating layer 74 and the backside insulating structure BIS may include the same material because the fourth interlayer insulating layer 74 and the backside insulating structure BIS are formed in the same process without being separately distinguished. In this case, the backside insulating layer 72 may be omitted.

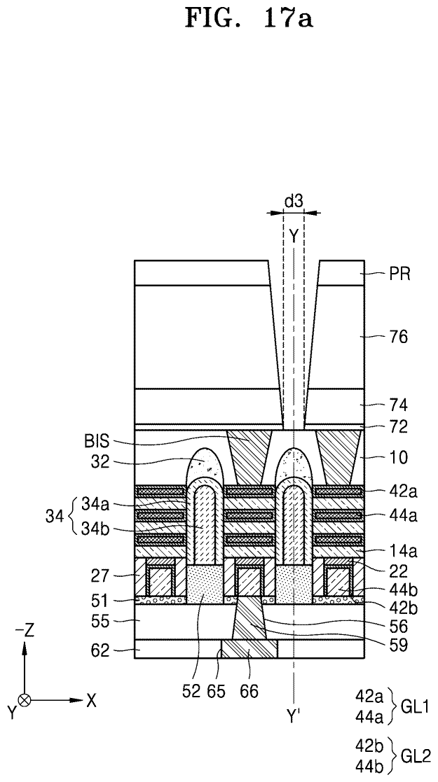

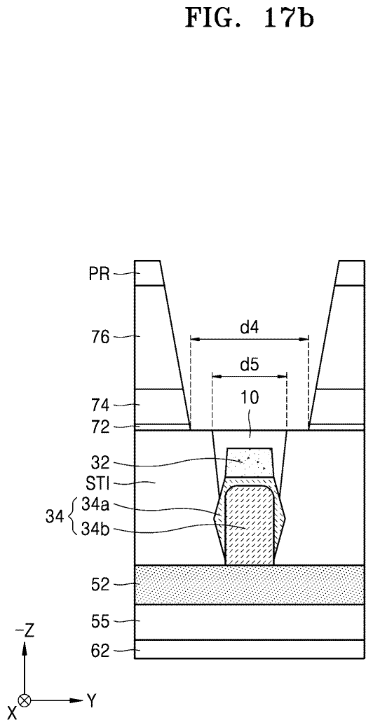

Referring to FIGS. 17A and 17B, a fifth interlayer insulating layer 76 may be formed on the fourth interlayer insulating layer 74, a photoresist layer PR may be formed thereon, and then a photolithography process may be performed to remove a portion of the fifth interlayer insulating layer 76, the fourth interlayer insulating layer 74, and the backside insulating layer 72 so that the back surface of the substrate 10 is again exposed, to form a hole. The hole may be formed at a position overlapping the placeholder 32 in the vertical direction (Z direction).

In this embodiment, the side surface of the hole formed in the fifth interlayer insulating layer 76, the fourth interlayer insulating layer 74, and the backside insulating layer 72 may have a tapered shape decreasing in width in the first horizontal direction (X direction) toward the back surface of the substrate 10. The width of the lower surface of the hole in the first horizontal direction (X direction) may be a third width d3, and the width thereof in the second horizontal direction (Y direction) may be a fourth width d4. In embodiments, the third width d3 may be equal to or different from the fourth width d4, and the size relationship between the third width d3 and the fourth width d4 may not affect embodiments of the inventive concept.

Referring to FIG. 17B, the fourth width d4 that is the diameter of the hole in the second horizontal direction (Y direction) may be greater than a fifth width d5 that is the width of the back surface of the substrate 10 arranged between shallow trench isolation (STI) structures. That is, the back surface of the substrate 10 may be entirely exposed by the hole in the second horizontal direction (Y direction) by the photolithography process described with reference to FIGS. 17A and 17B.

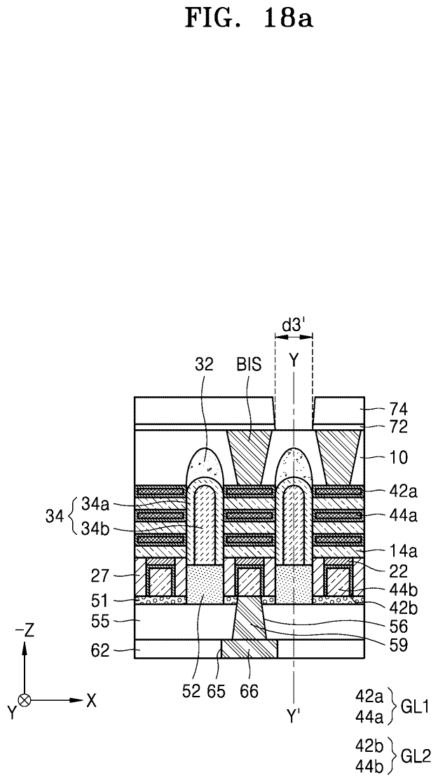

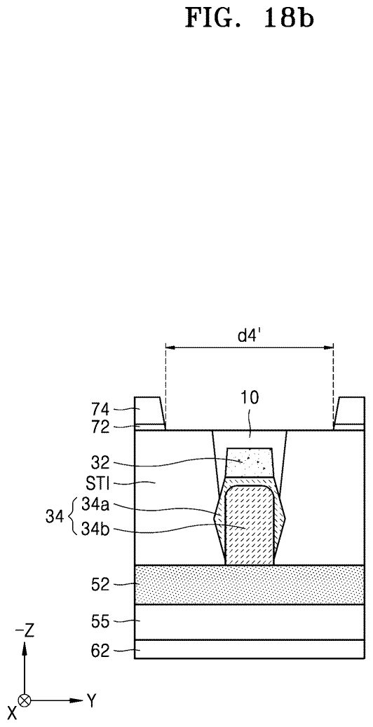

Referring to FIGS. 18A and 18B, the photoresist layer PR and the fifth interlayer insulating layer 76 may be removed, and the hole formed in FIGS. 17A and 17B may be further widened by a pull-back process. In the process, the height of the fourth interlayer insulating layer 74 in the vertical direction (Z direction) may be reduced, and at least a portion of the backside insulating layer 72 may also be further removed as the hole is widened.

Referring to FIG. 18A, by a pull-back process, a third width d3′ that is the width of the lower surface of the hole in the first horizontal direction (X direction) may have a greater value than the third width d3 that is the width of the lower surface of the hole in the first horizontal direction (X direction) in FIG. 17A. Likewise, referring to FIG. 18B, a fourth width d4′ that is the width of the lower surface of the hole in the second horizontal direction (Y direction) may have a greater value than the fourth width d4 that is the width of the lower surface of the hole in the second horizontal direction (Y direction) in FIG. 17B.

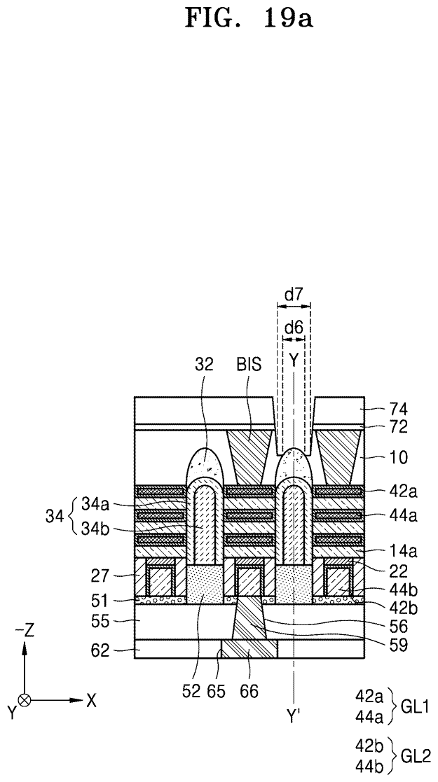

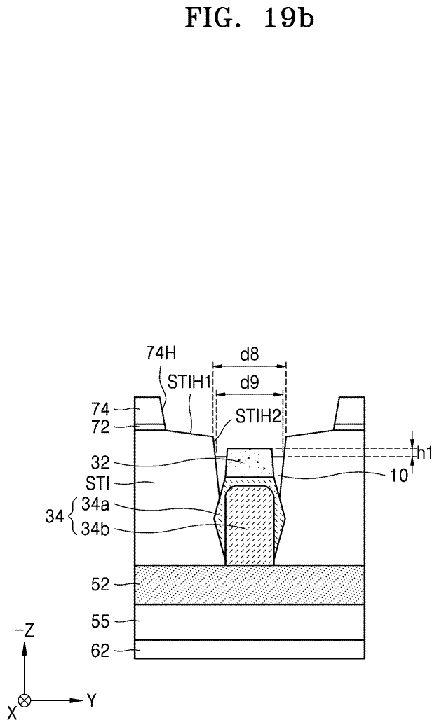

Next, referring to FIGS. 19A and 19B, a portion of the fourth interlayer insulating layer 74, the backside insulating layer 72, and the substrate 10 may be etched so that at least a portion of the placeholder 32 is exposed.

In FIG. 19A, an etching process is performed only on the upper portion of the placeholder 32 on the right side; however, this is only an example and a portion of the fourth interlayer insulating layer 74, the backside insulating layer 72, and the substrate 10 may also be etched so that the upper portion of the placeholder 32 on the left side of FIG. 19A is exposed.

By the etching process exposing at least a portion of the placeholder 32, at least one recess may be formed in the substrate 10. At the lower surface of the recess, a seventh width d7 that is the width of the lower surface of the recess formed in the substrate 10 in the first horizontal direction (X direction) may not be less than a sixth width d6 that is the width of the placeholder 32 exposed by the recess in the first horizontal direction (X direction). That is, in a plan view, the cross-sectional area where the placeholder 32 is exposed may be less than the cross-sectional area of the lower surface of the recess.

Referring to FIG. 19B, the recess may not have a uniform slope profile of the side surface in the second horizontal direction (Y direction). That is, a side surface of the recess may substantially have a tapered shape decreasing in width toward the source/drain region 34; however, the side surface may include some bends instead of extending with a uniform slope. The slope of the slope surface of an upper side surface STIH1 formed along the STI structure may be less than the slope of the slope surface of a lower side surface STIH2. That is, the slope of the slope surface at a portion where the upper side surface STIH1 and the lower side surface STIH2 are connected may be formed to be similar to a ‘Y’ shape. Also, the slope of a side surface 74H formed along the fourth interlayer insulating layer 74 and the backside insulating layer 72 may be greater than the slope of the upper side surface STIH1 formed along the STI structure.

Because the lower side surface STIH2 of the STI structure has a tapered shape decreasing in width toward the source/drain region 34, an eighth width d8 that is the width in the second horizontal direction (Y direction) at a vertical level contacting the upper side surface STIH1 may be greater than a ninth width d9 that is the width of the exposed lower surface of the substrate 10.

Because the placeholder 32 is at least partially exposed by the above process, the vertical level of the upper surface where the placeholder 32 is exposed may be greater by a first height h1 than the vertical level of the exposed lower surface of the substrate 10.

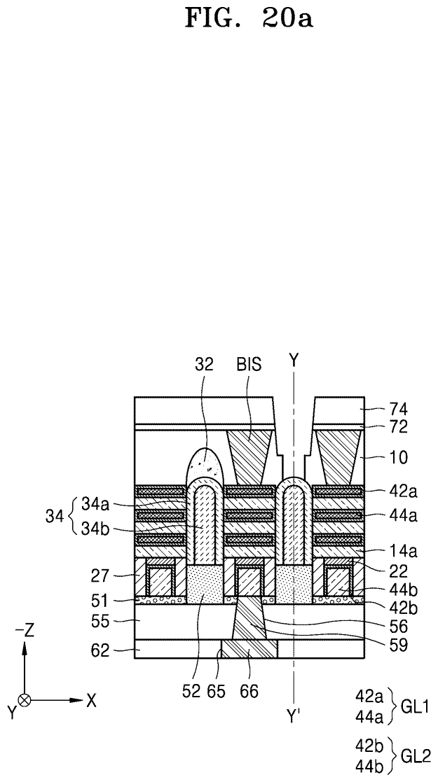

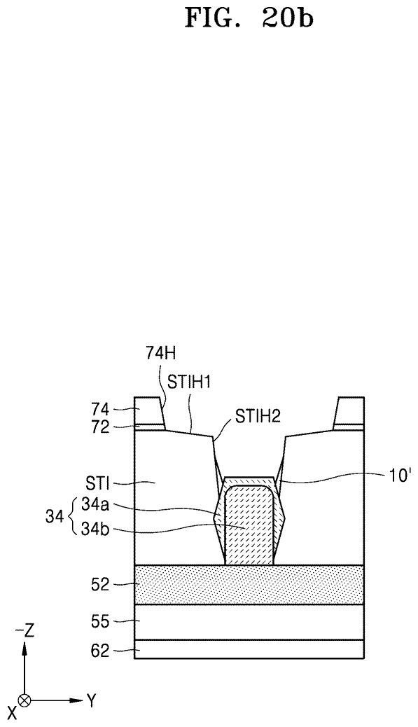

Referring to FIGS. 20A and 20B, the placeholder 32 at least partially exposed may be removed from the resulting structure of FIGS. 19A and 19B.

As the placeholder 32 is removed, a portion of the source/drain region 34 may be exposed. Also, referring to FIG. 20B, a portion of the substrate 10 (see FIG. 19B) covering a portion of the placeholder 32 may remain and thus a substrate material 10′ may remain on a portion of the lower side surface STIH2. However, this is only an example, and in some other embodiments, the substrate material 10′ may not remain and may be removed together with the placeholder 32.

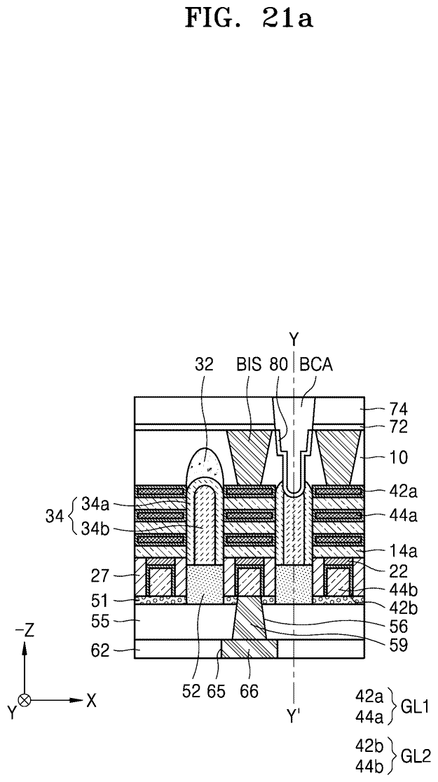

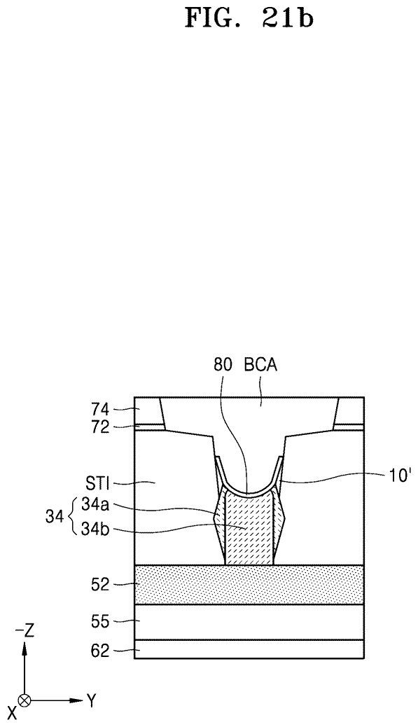

Referring to FIGS. 21A and 21B, a liner 80 and a backside contact BCA may be formed to at least partially fill the space where the placeholder 32 (see FIGS. 19A and 19B) has been arranged.

In embodiments, the liner 80 may include a silicide material. For example, the liner 80 may include at least one material selected from among TiSi, MoSi, RuSi, and CoSi, or any combination thereof. Referring to FIG. 21A, the liner 80 may extend to a vertical level lower than the backside insulating layer 72 in the first horizontal direction (X direction). Referring to FIG. 21B, the liner 80 may extend to a vertical level lower than a point where the upper side surface and the lower side surface of the STI structure intersect each other in the second horizontal direction (Y direction).

The backside contact BCA may at least partially fill a space in the liner 80 and may completely fill an empty space in the fourth interlayer insulating layer 74. That is, the upper surface of the backside contact BCA may be arranged at the same vertical level as the upper surface of the fourth interlayer insulating layer 74, i.e., the upper surface of the backside contact BCA may be coplanar with the upper surface of the fourth insulating layer 74. The backside contact BCA may include, for example, a metal material.

With reference to FIGS. 1-14, 15A, 15B, 16A, 16B, 17A, 17B, 18A, 18B, 19A, 19B, 20A, 20B, 21A, and 21B, a description has been given of and embodiment of the integrated circuit device in which the backside insulating structure BIS is formed on the back surface of the substrate 10 to implement the self-aligned backside contact BCA and improve the structural stability and electrical reliability thereof even without a process of removing the substrate 10. The integrated circuit device described above with reference to FIGS. 1-14, 15A, 15B, 16A, 16B, 17A, 17B, 18A, 18B, 19A, 19B, 20A, 20B, 21A, and 21B may include the placeholder 32 as a component thereof; however, another embodiment will be described below which may form a backside insulating structure BIS on the back surface of a substrate 10 even without including a placeholder and may stably implement a backside contact BCA without a process of removing the substrate 10.

In an embodiment not including a placeholder, the processes described above with reference to FIGS. 1 to 4 may be performed substantially in the same manner as the above embodiments. Hereinafter, descriptions of the same processes will be omitted and differences therebetween will be mainly described.

The subsequent processes may also be performed in the same manner as the processes described above with reference to FIGS. 5 to 14, FIG. 15A, FIG. 15B, FIG. 16A, FIG. 16B, FIG. 17A, and FIG. 17B, except that a source/drain region 34 is formed by selectively epitaxially growing a doped semiconductor material without forming a placeholder.

Referring to FIGS. 22A and 22B, the photoresist layer PR and the fifth interlayer insulating layer 76 may be removed from the resulting structure of FIGS. 17A and 17B, the hole formed in FIGS. 17A and 17B may be further widened by a pull-back process, and the substrate over the source/drain region 34 may be etched to at least partially expose the source/drain region 34. In the process, the height of the fourth interlayer insulating layer 74 in the vertical direction (Z direction) may be reduced, and at least a portion of the backside insulating layer 72 may also be further removed as the hole is widened.

At least a portion of the upper surface of the source/drain region 34 may be exposed by the process. In FIG. 22A, the hole formed in the substrate 10 is illustrated as completely overlapping the source/drain region 34 in the vertical direction; however, in some other embodiments, the hole in the substrate 10 and the source/drain region 34 may only partially overlap each other instead of completely overlapping each other. Referring to FIG. 20B, a portion of the substrate 10 (see FIG. 19B) may remain and thus a substrate material 10′ may remain on a portion of the lower side surface STIH2. However, this is only an example, and in some other embodiments, the substrate material 10′ may not remain and may be removed together with the placeholder 32.

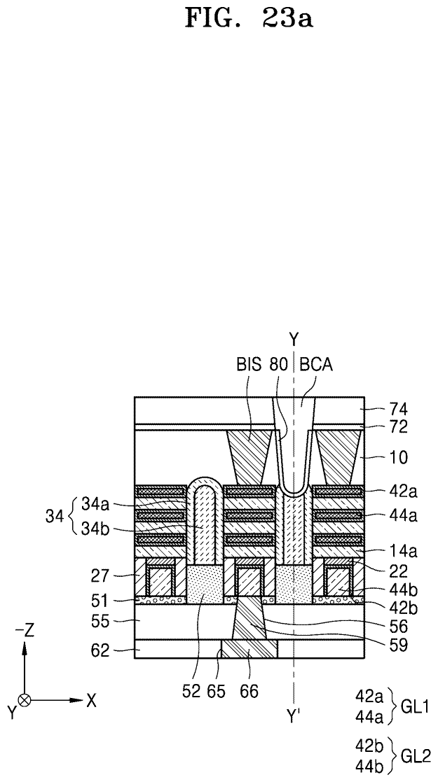

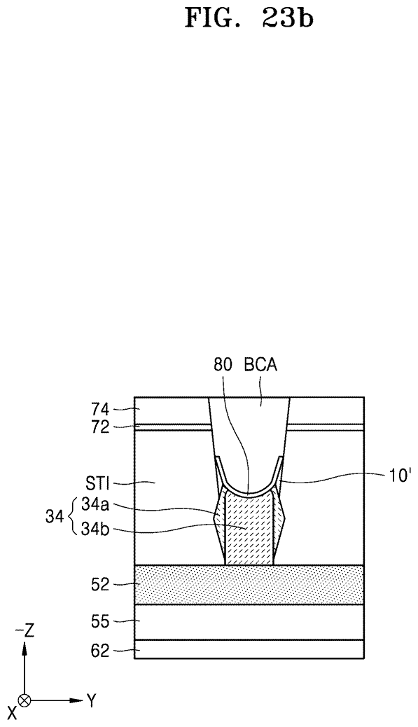

Referring to FIGS. 23A and 23B, a liner 80 may be formed on at least a portion of the wall surface of the hole and a backside contact BCA may be formed to at least partially fill the remaining space.

In embodiments, the liner 80 may include a silicide material. For example, the liner 80 may include at least one material selected from among TiSi, MoSi, RuSi, CoSi, or any combination thereof. Referring to FIG. 23A, the liner 80 may extend to a vertical level lower than the backside insulating layer 72 in the first horizontal direction (X direction). Referring to FIG. 23B, the liner 80 may extend to a vertical level where the substrate material 10′ remains in the second horizontal direction (Y direction).

The backside contact BCA may at least partially fill a space in the liner 80 and may completely fill an empty space in the fourth interlayer insulating layer 74. That is, the upper surface of the backside contact BCA may be arranged at the same vertical level as the upper surface of the fourth interlayer insulating layer 74 i.e., the upper surface of the backside contact BCA may be coplanar with the upper surface of the fourth insulating layer 74. The backside contact BCA may include, for example, a metal material.

The embodiments not including the placeholder have been described above. Embodiments of the inventive concept may provide the integrated circuit device with improved reliability by forming the backside insulating structure BIS on the back surface of the substrate 10, even in the case of not including the placeholder and by stably implementing the backside contact BCA without a process of removing the substrate 10.

While the inventive concept has been particularly shown and described with reference to embodiments thereof, it will be understood that various changes in form and details may be made therein without departing from the spirit and scope of the following claims.

What is claimed is:

1. A method of manufacturing an integrated circuit device, the method comprising:
alternately stacking a plurality of sacrificial layers and a plurality of channel layers on a first surface of a substrate including the first surface and a second surface opposite to the first surface;
etching a portion of each of the plurality of sacrificial layers and the plurality of channel layers to divide the plurality of channel layers into a plurality of nanosheet stacks;
forming a placeholder and a source/drain region on the placeholder between the plurality of nanosheet stacks;
removing the plurality of sacrificial layers and forming a first gate structure including a gate dielectric layer and a gate line in an area from which the plurality of sacrificial layers have been removed;
etching a portion of the second surface of the substrate in an area where the first gate structure is arranged in a plan view to form an opening in the substrate and forming a backside insulating structure in the opening including a lower surface facing the first surface of the substrate and an upper surface facing the second surface of the substrate;
etching the substrate so that at least a portion of the placeholder is exposed;
removing the placeholder; and
forming a liner on at least a portion of a side surface of the substrate from which the placeholder has been removed and forming a backside contact on the liner.

2. The method of claim 1, wherein the backside contact at least partially overlaps the source/drain region in a plan view.

3. The method of claim 1, wherein the lower surface of the backside insulating structure is formed to at least partially contact the first gate structure.

4. The method of claim 3, wherein the lower surface of the backside insulating structure is formed to entirely contact the first gate structure.

5. The method of claim 1, wherein the backside insulating structure has a tapered shape decreasing in width from the second surface toward the first surface of the substrate.

6. The method of claim 1, wherein the liner is between the backside contact and the source/drain region and between the backside contact and the backside insulating structure.

7. The method of claim 1, wherein the backside contact has a tapered shape, such that the backside contact has a greater width adjacent the second surface of the substrate than adjacent the first surface of the substrate and includes a downwardly-convexed protrusion portion adjacent the first surface of the substrate.

8. The method of claim 7, wherein a width of the source/drain region is different from a width of a lowermost surface of the placeholder in a direction parallel with planes formed by the first and second surfaces of the substrate.

9. The method of claim 1, wherein the liner comprises a silicide material.

10. The method of claim 1, wherein a spacing distance between a surface of the backside contact opposite to the source/drain region and the first surface of the substrate is greater than a spacing distance between the upper surface of the backside insulating structure and the first surface of the substrate.

11. The method of claim 1, wherein the liner does not protrude from a plane defined by the upper surface of the backside insulating structure in a direction extending from the first substrate of the substrate to the second surface of the substrate perpendicular to the plane defined by the upper surface of the backside insulating structure.

12. The method of claim 1, wherein the etching of the substrate so that at least the portion of the placeholder is exposed comprises etching the substrate so that an upper surface of the placeholder is exposed.

13. A method of manufacturing an integrated circuit device, the method comprising:
alternately stacking a plurality of sacrificial layers and a plurality of channel layers layer by layer on a first surface of a substrate including the first surface and a second surface opposite to the first surface;
etching a portion of each of the plurality of sacrificial layers and the plurality of channel layers to divide the plurality of channel layers into a plurality of nanosheet stacks;
forming a source/drain region between the plurality of nanosheet stacks;
removing the plurality of sacrificial layers and forming a first gate structure including a gate dielectric layer and a gate line in an area from which the plurality of sacrificial layers have been removed;
etching a portion of the second surface of the substrate in an area where the first gate structure is arranged in a plan view to form an opening in the substrate and forming a backside insulating structure in the opening including a lower surface facing the first surface of the substrate and an upper surface facing the second surface of the substrate;
etching the substrate so that at least a portion of the source/drain region is exposed; and
forming a liner on an exposed surface of the source/drain region and on at least a portion of a side surface of the substrate and forming a backside contact on the liner.

14. The method of claim 13, wherein the lower surface of the backside insulating structure is formed to at least partially contact the first gate structure.

15. The method of claim 14, wherein the lower surface of the backside insulating structure is formed to entirely contact the first gate structure.

16. The method of claim 13, wherein the backside insulating structure and the backside contact are formed in a tapered shape, such that each has a greater width adjacent the second surface of the substrate than adjacent the first surface of the substrate.

17. The method of claim 13, wherein the liner is between the backside contact and the source/drain region and between the backside contact and the backside insulating structure.

18. The method of claim 13, wherein the liner does not protrude from a plane defined by the upper surface of the backside insulating structure in a direction extending from the first substrate of the substrate to the second surface of the substrate perpendicular to the plane defined by the upper surface of the backside insulating structure.

19. The method of claim 13, wherein a spacing distance between a surface of the backside contact opposite to the source/drain region and the first surface of the substrate is greater than a spacing distance between the upper surface of the backside insulating structure and the first surface of the substrate.

20. A method of manufacturing an integrated circuit device, the method comprising:
forming a placeholder, a source/drain region, and a first gate structure including a gate dielectric layer and a gate line on a first surface of a substrate including the first surface and a second surface opposite to the first surface;
etching a portion of the second surface of the substrate in an area where the first gate structure is arranged in a plan view to form an opening in the substrate and forming a backside insulating structure in the opening;
forming a backside insulating layer on an upper surface of the backside insulating structure and the second surface of the substrate, and an interlayer insulating layer on the backside insulating layer;
removing a portion of the interlayer insulating layer and the backside insulating layer to expose a portion of the substrate and forming a hole in the substrate so that at least a portion of the placeholder is exposed;
removing the placeholder and forming a silicide liner on a side surface and a lower surface of the hole, to a vertical level lower than a vertical level of the backside insulating layer where the first surface of the substrate provides a base reference plane and the second surface of the substrate is above the first surface of the substrate, in a space from which the placeholder has been removed; and
forming a backside contact in a space bordered by the liner and an empty space in the interlayer insulating layer.
